(19) United States
(12) Patent Application Publication
(10) Pub. No.: US 2026/0341222 A1
(43) Pub. Date: Oct. 29, 2026

(54) DISPLAY SUBSTRATE AND MANUFACTURING METHOD THEREOF, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Qingqing YAN, Beijing (CN); Ziyang YU, Beijing (CN); Qing HE, Beijing (CN); Tiaomei ZHANG, Beijing (CN); Xiangnan PAN, Beijing (CN); Zhiliang JIANG, Beijing (CN); Ming HU, Beijing (CN)

(21) Appl. No.: 18/995,793

(22) PCT Filed: Sep. 27, 2023
(86) PCT No.: PCT/CN2023/122352

§ 371 Date: Jan. 16, 2025

(51) Int. Cl. G09G 3/3266

(52) U.S. Cl. CPC G09G 3/3266; G09G 2300/0426; G09G 2330/021

(57) ABSTRACT

The present disclosure provides a display substrate, a manufacturing method thereof, and a display device. The display substrate includes a row addressing region, a first pixel driving region, and a second pixel driving region. The row addressing region is provided with a row addressing circuit. The first pixel driving region is located on one side of the row addressing region. The second pixel driving region is located on the other side of the row addressing region, and the row addressing region is located between the first pixel driving region and the second pixel driving region.

### TECHNICAL FIELD

The present disclosure relates to the field of display technology, and in particular to a display substrate and a manufacturing method thereof, and a display device.

### BACKGROUND

At present, there is an increasing demand for long battery life in electronic devices such as mobile phones and tablet computers in the market. This requires reducing the power consumption of the display substrate. Usually, different regions different frequencies (i.e., different regions of the screen support different refresh rates) can be used to achieve reducing power consumption. The screen with different regions different frequencies function is divided into multiple regions, and each region can be set with a different refresh rate. Different regions different frequencies can achieve that a refreshed region updates, and a non-refresh region maintains the data from the previous frame, which further saves display power consumption.

### SUMMARY

The present disclosure provides a display substrate and a manufacturing method thereof, and a display device.

According to the first aspect of the embodiments of the present disclosure, a display substrate is provided. The display substrate includes:
a row addressing region, provided with a row addressing circuit;
a first pixel driving region on one side of the row addressing region, where the first pixel driving region is provided with a pixel circuit; and
a second pixel driving region, located on the other side of the row addressing region, and provided with a pixel circuit, where the row addressing region is located between the first pixel driving region and the second pixel driving region;
where the row addressing circuit includes:
a scan driving circuit;
a first gating circuit between the scan driving circuit and the first pixel driving region, where the first gating circuit connects the scan driving circuit and the pixel circuit in the first pixel driving region; and
a second gating circuit between the scan driving circuit and the second pixel driving region, where the second gating circuit connects the scan driving circuit and the pixel circuit in the second pixel driving region.

In some embodiments, the display substrate further includes:
a base;
a driving circuit layer on a side of the base; and
an organic light-emitting layer on a side of the driving circuit layer away from the base;
where the driving circuit layer includes the row addressing circuit of the row addressing region.

In some embodiments, the pixel circuit in the first pixel driving region and the pixel circuit in the second pixel driving region are in the driving circuit layer, and the pixel circuit in the first pixel driving region includes a capacitor and thin film transistors and is configured to control light emission of a pixel, and the pixel circuit in the second pixel driving region includes a capacitor and thin film transistors and is configured to control light emission of a pixel;
where the row addressing circuit of the row addressing region is in a same layer as the pixel circuit in the first pixel driving region and the pixel circuit in the second pixel driving region.

In some embodiments, the base includes a rigid substrate and/or a flexible substrate.

In some embodiments, the display substrate further include: a bottom shielding layer between the base and the driving circuit layer.

In some embodiments, the bottom shielding layer includes connecting wires and shielding patterns, where the connecting wires electrically connect the shielding patterns into a whole.

In some embodiments, one of the shielding patterns includes a horizontal shielding line extending along a first direction, a vertical shielding line extending along a second direction, and a square shielding block at an intersection of the horizontal shielding line and the vertical shielding line.

In some embodiments, the display substrate further include: a buffer layer between the driving circuit layer and the base.

In some embodiments, the driving circuit layer includes:
a first active layer;
a first gate layer;
a second gate layer on a side of the first gate layer and the first gate layer away from the base;
a second active layer; and
a third gate layer on a side of the second gate layer away from the base.

In some embodiments, the material of the first active layer includes amorphous silicon or polycrystalline silicon.

In some embodiments, the first active layer includes first active regions, where each of the first active regions corresponds to a thin film transistor or a plurality of electrically connected thin film transistors; and
the first active regions are provided in the row addressing region, the first pixel driving region, and the second pixel driving region.

In some embodiments, the first gate layer located in the first pixel driving region and the second pixel driving region includes a first type gate line extending along a first direction, and gate pattern blocks;
where the gate pattern blocks are block-shaped, and some of the gate pattern blocks are arranged in a row along a first direction.

In some embodiments, the first gate layer in the row addressing region includes a first type gate line extending along a first direction, a second type gate line extending both along the first direction and a second direction, block-shaped gate pattern blocks, and U-shaped third type gate lines.

In some embodiments, the third type gate line includes a horizontal connecting line extending along the first direction, and two vertical gate portions respectively arranged at both ends of the horizontal connecting line, where the two vertical gate portions are parallel and spaced apart from each other.

In some embodiments, the first gate layer includes a first gate connecting line for connecting a gate line on any one of two sides of the row addressing region.

In some embodiments, the first gate connecting line includes a gate connecting end connecting to the gate line, an away gate end in the row addressing region and away from the gate line, and a winding line segment located between the gate connecting end and the away gate end and connecting the gate connecting end and the away gate end, where the gate connecting end and/or the away gate end extends along a first direction, and the winding line segment extends along a second direction.

In some embodiments, the first gate layer includes a second gate connecting line for connecting a gate line on any one of two sides of the row addressing region, one end of the second gate connecting line is connected to the gate line, and the other end of the second gate connecting line does not extend to a region of the scan driving circuit of the row addressing region.

In some embodiments, the second gate layer located in the first pixel driving region and the second pixel driving region includes a fourth type gate line extending along a first direction, and gate pattern blocks;
where at least one portion of the fourth type gate line and a corresponding portion of the first gate layer form a capacitor, and at least one portion of one of the gate pattern blocks and a corresponding portion of the first gate layer form a capacitor.

In some embodiments, the second gate layer in the row addressing region includes a fourth type gate line extending along a first direction, a fifth type gate line extending both along the first direction and a second direction, block-shaped gate pattern blocks, and U-shaped sixth type gate lines.

In some embodiments, the sixth type gate line includes a horizontal connecting line extending along the first direction, and two vertical gate portions respectively arranged at both ends of the horizontal connecting line, where the two vertical gate portions are parallel and spaced apart from each other;
where one of the gate pattern blocks and a corresponding portion of the first gate layer form a capacitor.

In some embodiments, the second gate layer includes a third gate connecting line for connecting a gate line on any one of two sides of the row addressing region;
where the third gate connecting line includes a middle connecting segment, two near gate ends, and two vertical segments, where the middle connecting segment is in a middle region of the row addressing region and extends along the first direction to both sides of the row addressing region, the two near gate ends are located on opposite sides of the gate connecting line along the first direction, and the vertical segments each extends along the second direction and is connected between the middle connecting segment and one of the two near gate ends.

In some embodiments, the material of the second active layer includes metal oxide.

In some embodiments, the third gate layer located in the first pixel driving region and the second pixel driving region includes a first type gate line extending along a first direction.

In some embodiments, the third gate layer in the row addressing region includes a first type gate line extending along a first direction, a second type gate line extending both along the first direction and a second direction, and U-shaped third type gate lines;
where the third type gate line includes a horizontal connecting line extending along the first direction, and two vertical gate portions respectively arranged at both ends of the horizontal connecting line, where the two vertical gate portions are parallel and spaced apart from each other.

In some embodiments, the third gate layer includes a third gate connecting line for connecting a gate line on any one of two sides of the row addressing region;
where the third gate connecting line includes a middle connecting segment, two near gate ends, and two vertical segments, where the middle connecting segment is in a middle region of the row addressing region and extends along the first direction to both sides of the row addressing region, the two near gate ends are located on opposite sides of the gate connecting line along the first direction, and the vertical segments each extends along the second direction and is connected between the middle connecting segment and one of the two near gate ends.

In some embodiments, the display substrate further includes:
a second row addressing region at an edge of the display substrate, where the second row addressing region is provided with a second row addressing circuit; and
a third pixel driving region between the second row addressing region and the first pixel driving region;
where the second row addressing circuit includes:
a second scan driving circuit;
a third gating circuit between the second scan driving circuit and the third pixel driving region, where the third gating circuit connects the second scan driving circuit and a pixel circuit in the third pixel driving region.

In some embodiments, the display substrate further includes:
a third row addressing region at another edge of the display substrate, where the third row addressing region is provided with a third row addressing circuit; and
a fourth pixel driving region between the second pixel driving region and the third row addressing region;
where the third row addressing circuit includes:
a third scan driving circuit;
a fourth gating circuit between the third scan driving circuit and the fourth pixel driving region, where the fourth gating circuit connects the third scan driving circuit and a pixel circuit in the fourth pixel driving region.

In some embodiments, the display substrate further includes:
a fourth row addressing region provided with a fourth row addressing circuit;
a fifth pixel driving region between the fourth row addressing region and the third pixel driving region; and
a sixth pixel driving region between the fourth row addressing region and the first pixel driving region;
where the fourth row addressing circuit includes:
a fourth scan driving circuit;
a fifth gating circuit between the fourth scan driving circuit and the fifth pixel driving region, where the fifth gating circuit connects the fourth scan driving circuit and a pixel circuit in the fifth pixel driving region.
a sixth gating circuit between the fourth scan driving circuit and the sixth pixel driving region, where the sixth gating circuit connects the fourth scan driving circuit and a pixel circuit in the sixth pixel driving region.

In some embodiments, a number of pixels in each row of the first pixel driving region is equal to a number of pixels in each row of the second pixel driving region; and/or a number of pixels in each row of the fifth pixel driving region is equal to a number of pixels in each row of the sixth pixel driving region.

In some embodiments, a refresh rate of the first pixel driving region and a refresh rate of the second pixel driving region are independently controlled by the row addressing circuit of the row addressing region.

According to the second aspect of the embodiments of the present disclosure, a method for manufacturing a display substrate as described above is provided, including:
providing a base;
forming a row addressing region, a first pixel driving region, and a second pixel driving region on the base, where the row addressing region is provided with a row addressing circuit; the first pixel driving region is on one side of the row addressing region, and is provided with a pixel circuit; and the second pixel driving region is on the other side of the row addressing region, and is provided with a pixel circuit; where the row addressing region is between the first pixel driving region and the second pixel driving region;
where the row addressing circuit includes:
a scan driving circuit;
a first gating circuit between the scan driving circuit and the first pixel driving region, where the first gating circuit connects the scan driving circuit and the pixel circuit in the first pixel driving region; and
a second gating circuit between the scan driving circuit and the second pixel driving region, where the second gating circuit connects the scan driving circuit and the pixel circuit in the second pixel driving region.

In some embodiments, the method further includes:
forming a driving circuit layer on a side of the base, where the driving circuit layer includes pixel circuits in the first pixel driving region and the second pixel driving region, and a row addressing circuit in the row addressing region, where each of the pixel circuit in the first pixel driving region, the pixel circuit in the second pixel driving region, and the row addressing circuit in the row addressing region includes a capacitor and thin film transistors; and
forming an organic light-emitting layer on a side of the driving circuit layer away from the base.

According to the third aspect of the embodiments of the present disclosure, a display device including the display substrate as described above is provided.

### BRIEF DESCRIPTION OF DRAWINGS

FIG. 1 is a schematic diagram of a top structure of a display substrate provided in an embodiment of the present disclosure.

FIG. 2 is a schematic diagram of a top structure of a display substrate provided in another embodiment of the present disclosure.

FIG. 3 is a principle schematic diagram of a row addressing circuit located in a row addressing region provided in an embodiment of the present disclosure.

FIG. 4 is a cross-segmental schematic diagram of a display substrate provided in an embodiment of the present disclosure.

FIG. 5 is a schematic diagram of a layout structure of a bottom shielding layer provided in an embodiment of the present disclosure.

FIG. 6 is a schematic diagram of a layout structure of an active layer provided in an embodiment of the present disclosure.

FIG. 7 is a schematic diagram of a layout structure of an active layer stacked on a bottom shielding layer provided in an embodiment of the present disclosure.

FIG. 8 is a schematic diagram of a layout structure of a first gate layer provided in an embodiment of the present disclosure.

FIG. 9 is a schematic diagram of a layout structure of a first gate layer stacked on an active layer provided in an embodiment of the present disclosure.

FIG. 10 is a schematic diagram of a layout structure of a second gate layer provided in an embodiment of the present disclosure.

FIG. 11 is a schematic diagram of a layout structure of a second gate layer stacked on a first gate layer provided in an embodiment of the present disclosure.

FIG. 12 is a schematic diagram of a layout structure of an active layer provided in an embodiment of the present disclosure.

FIG. 13 is a schematic diagram of a layout structure of an active layer stacked on a second gate layer provided in an embodiment of the present disclosure.

FIG. 14 is a schematic diagram of a layout structure of a third gate layer provided in an embodiment of the present disclosure.

FIG. 15 is a schematic diagram of a layout structure of a third gate layer stacked on an active layer provided in an embodiment of the present disclosure.

FIG. 16 is a schematic diagram of a layout structure of an interlayer dielectric layer provided in an embodiment of the present disclosure.

FIG. 17 is a schematic diagram of a layout structure of a first source-drain electrode layer provided in an embodiment of the present disclosure.

FIG. 18 is a schematic diagram of a layout structure of a first source-drain electrode layer stacked on an interlayer dielectric layer provided in an embodiment of the present disclosure.

FIG. 19 is a schematic diagram of a layout structure of a first planarization layer provided in an embodiment of the present disclosure.

FIG. 20 is a schematic diagram of a layout structure of a second source-drain electrode layer provided in an embodiment of the present disclosure.

FIG. 21 is a schematic diagram of a layout structure of a second source-drain electrode layer stacked on a first planarization layer provided in an embodiment of the present disclosure.

FIG. 22 is a schematic diagram of a layout structure of a second planarization layer provided in an embodiment of the present disclosure.

FIG. 23 is a schematic diagram of a layout structure of a transparent electrode layer provided in an embodiment of the present disclosure.

FIG. 24 is a schematic diagram of a layout structure of a third planarization layer provided in an embodiment of the present disclosure.

FIG. 25 is a schematic diagram of a layout structure of an anode layer provided in an embodiment of the present disclosure.

FIG. 26 is a schematic diagram of a top structure of a display substrate provided in another embodiment of the present disclosure.

FIG. 27 is a schematic diagram of a top structure of a display substrate provided in another embodiment of the present disclosure.

### DETAILED DESCRIPTION

Embodiments will be described in detail here with the examples thereof expressed in the drawings. When the following descriptions involve the drawings, like numerals in different drawings represent like or similar elements unless stated otherwise. The examples described in the following examples do not represent all examples consistent with the present disclosure. Rather, they are merely embodiments of devices and methods consistent with some aspects of the present disclosure as recited in the appended claims.

Terms used in the present disclosure is only for the purpose of describing particular embodiments and is not intended to limit the present disclosure. As used in the present disclosure and the appended claims, the singular forms “a”, “said” and “the” are intended to include the plural” and “the” are intended to include the plural forms as well, unless the context clearly dictates otherwise. It should further be understood that the term “and/or” as used herein refers to and includes any and all possible combinations of one or more of the associated listed items.

It shall be understood that, although the terms “first,” “second,” “third,” and the like may be used herein to describe various information, the information should not be limited by these terms. These terms are only used to distinguish the same type of information from each other. For example, without departing from the scope of the present disclosure, first information may be referred as second information; and similarly, second information may also be referred as first information. Depending on the context, the word “if” as used herein can be interpreted as “at the time of”, “when” or “in response to determining”.

Below, with reference to the accompanying drawings, a detailed description will be given of the display substrate and a manufacturing method thereof, and a display device in the embodiments of the present disclosure. In non-conflicting situations, the features in the following embodiments can complement or be combined with each other.

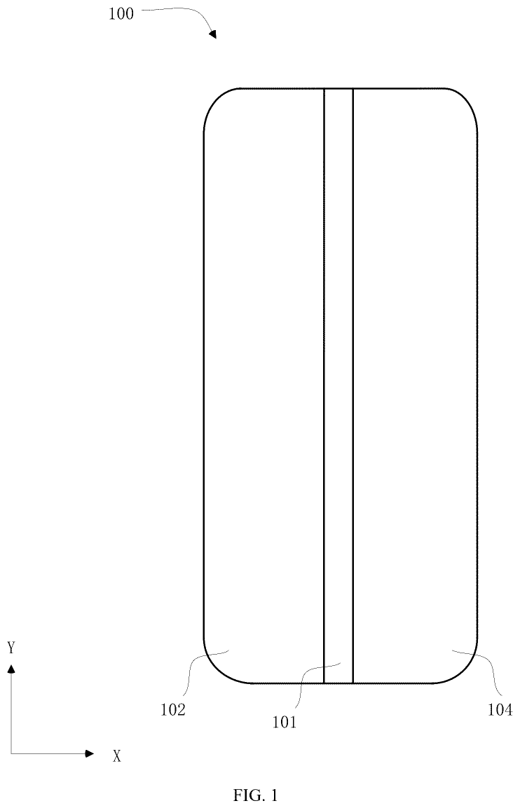

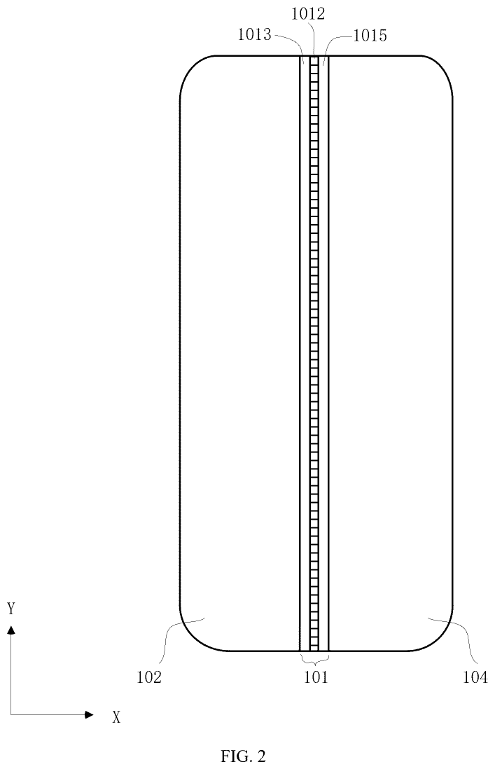

The embodiments of the present disclosure provide a display substrate. As shown in FIGS. 1 and 2, the display substrate 100 includes:
a row addressing region 101, provided with a row addressing circuit;
a first pixel driving region 102, located on one side of the row addressing region 101, and provided with a pixel circuit; and
a second pixel driving region 104, located on the other side of the row addressing region 101, where the row addressing region 101 is located between the first pixel driving region 102 and the second pixel driving region 104;
where the row addressing circuit in the row addressing region 101 includes:
a scan driving circuit 1012;
a first gating circuit 1013, located between the scan driving circuit 1012 and the first pixel driving region 102, and connecting the scan driving circuit 1012 and a pixel circuit in the first pixel driving region 102; and
a second gating circuit 1015, located between the scan driving circuit 1012 and the second pixel driving region 104, and connecting the scan driving circuit 1012 and a pixel circuit in the second pixel driving region 104.

In the display substrate provided in the embodiments of the present disclosure, the row addressing region is provided between the first pixel driving region and the second pixel driving region, such that the refresh rates of the first pixel driving region and the second pixel driving region on both sides of the same row addressing region can be conveniently controlled. Furthermore, the first gating circuit is connected between the scan driving circuit and the pixel circuit of the first pixel driving region, such that the row addressing circuit can control the refresh rates of the pixels in the first pixel driving region relatively independently. The second gating circuit is connected between the scan driving circuit and the pixel circuit of the second pixel driving region, such that the row addressing circuit can control the refresh rates of the pixels in the second pixel driving region relatively independently. Therefore, the above settings enable the refresh rates of the first pixel driving region and the second pixel driving region located in different regions to be relatively independently adjusted, achieving different regions different frequencies, which is beneficial for reducing display power consumption.

In some embodiments, the turn-on voltage can be provided to each row of the row addressing region in a certain order (such as row by row, interlaced, or a pre-set order) through the scan driving circuit. The first gating circuit selectively provides, according to received control signal, the turn-on voltage applied to each row of the row addressing region to a gate line of each row of the first pixel driving region, to achieve a predetermined refresh rate in the first pixel driving region; and the second gating circuit selectively conducts or does not conduct, according to the received control signal, the turn-on voltage applied to each row of the row addressing region to a gate line of each row of the second pixel driving region, to achieve a predetermined refresh rate in the second pixel driving region. According to actual needs, the refresh rate of the second pixel driving region can be the same as or different from the refresh rate of the first pixel driving region. The refresh rate of the first pixel driving region and the refresh rate of the second pixel driving region are independently adjustable.

In some embodiments, the first pixel driving region 102, the row addressing region 101, and the second pixel driving region 104 are sequentially arranged along a first direction X. The row addressing region 101 mainly extends along a second direction Y.

In some embodiments, the display substrate 100 is applied to a foldable display screen, such as a foldable phone, a foldable notebook, or a foldable tablet. The row addressing region 101 can be provided in the folding region, which can avoid reducing an area of a normal display region.

In some embodiments, the scan driving circuit 1012 includes a shift register that generates a shift pulse signal (turn-on voltage) under the control signal of an external circuit. The shift pulse signal is used to drive the pixels of the current row to turn on the corresponding thin film transistors (TFT) of the pixel row, and further serves as the start signal of the current row and the end signal of the previous row for control. The shift register is usually composed of a thin film transistor and a capacitor. For example, the 4T1C shift register or scan driving circuit includes 4 thin film transistors and 1 capacitor. The 8T1C shift register or scan driving circuit includes 8 thin film transistors and 1 capacitor.

In the case of non-line-by-line scanning, the scanning driver circuit 1012 can be a circuit other than the shift register, which can also be composed of multiple thin film transistors and capacitor(s) to provide the turn-on voltage to each row of the row addressing region in a certain order.

In some embodiments, the first gating circuit 1013 includes one or more thin film transistors. For example, the first gating circuit 1013 may be composed of multiple thin film transistors connected in parallel and series, used to selectively conduct or not conduct the turn-on voltage applied to each row of the row addressing region to the gate line of each row of the first pixel driving region according to the control signal received by the first gating circuit 1013. The second gating circuit 1015 includes one or more thin film transistors. For example, the second gating circuit 1015 may be composed of multiple thin film transistors connected in parallel and series, used to selectively conduct or not conduct the turn-on voltage applied to each row of the row addressing region to the gate line of each row of the second pixel driving region according to the control signal received by the second gating circuit 1015.

An embodiment of the row addressing circuit in row addressing region 101 is shown in FIG. 3.

In the embodiment shown in FIG. 3, the first gating circuit 1013 includes a first transistor T1, a second transistor T2, a third transistor T3, . . . , and a twelfth transistor T12.

The first pole of the first transistor T1 is connected to the first power signal VGHN, the gate of the first transistor T1 is connected to the first clock signal NCK_inv, and the second pole of the first transistor T1 is connected to the first pole of the second transistor T2. The second pole of the second transistor T2 is connected to the first pole of the third transistor T3 and to the first scan signal Nscan [n]_inv, and the gate of the second transistor T2 is connected to the second scan signal Nscan [n-1]. The second pole of the third transistor T3 is connected to the first pole of the fourth transistor T4, and the gate of the third transistor T3 is connected to the second scan signal Nscan [n-1]. The second pole of the fourth transistor T4 is connected to the second power signal VGLN, and the gate of the fourth transistor T4 is connected to the second clock signal NCK.

The first pole of the fifth transistor T5 is connected to the first power signal VGHN, the second pole of the fifth transistor T5 is connected to the first pole of the sixth transistor T6, and the gate of the fifth transistor T5 is connected to the third scan signal Nscan [n]. The second pole of the sixth transistor T6 is connected to the first pole of the seventh transistor T7, and the gate of the sixth transistor T6 is connected to the second clock signal NCK. The second pole of the seventh transistor T7 is connected to the first pole of the eighth transistor T8, and the gate of the seventh transistor T7 is connected to the gate of the first transistor T1 and to the first clock signal NCK_inv. The second pole of the eighth transistor T8 is connected to the second power signal VGLN, and the gate of the eighth transistor T8 is connected to the gate of the fifth transistor T5 and to the third scan signal Nscan [n].

The first pole of the ninth transistor T9 is connected to the first power signal VGHN, the second pole of the ninth transistor T9 is connected to the first pole of the tenth transistor T10 and to the first clock signal NCK_inv, and the gate of the ninth transistor T9 is connected to the second clock signal NCK. The second pole of the tenth transistor T10 is connected to the second power signal VGLN, and the gate of the tenth transistor T10 is connected to the second clock signal NCK. The first pole of the eleventh transistor T11 is connected to the first power signal VGHN, the second pole of the eleventh transistor T11 is connected to the first pole of the twelfth transistor T12 and to the third scan signal Nscan [n], and the gate of the eleventh transistor T11 is connected to the first scan signal Nscan [n]_inv. The second pole of the twelfth transistor T12 is connected to the second power signal VGLN, and the gate of the twelfth transistor T12 is connected to the first scan signal Nscan [n]_inv.

In the embodiment shown in FIG. 3, the scan driving circuit 1012 may include a thirteenth transistor T13, a fourteenth transistor T14, . . . , and a twentieth transistor T20, and a capacitor C0.

The first pole of the thirteenth transistor T13 is connected to the third scan signal Nscan [n], the gate of the thirteenth transistor T13 is connected to the control signal NCX, and the second pole of the thirteenth transistor T13 is connected to the first pole of the fourteenth transistor T14 and to the first power supply signal VGHN. The second pole of the fourteenth transistor T14 is connected to the N11 node, and the gate of the fourteenth transistor T14 is connected to the control signal NCX. The first pole of the fifteenth transistor T15 is connected to the first power supply signal VGHN, the gate of the fifteenth transistor T15 is connected to the second scan signal Nscan [n-1], and the second pole of the fifteenth transistor T15 is connected to the first pole of the sixteenth transistor T16. The second pole of the sixteenth transistor T16 is connected to the first pole of the seventeenth transistor T17 and to the N11 node, and the gate of the sixteenth transistor T16 is connected to the third scan signal Nscan [n].

The second pole of the seventeenth transistor T17 is connected to the first pole of the eighteenth transistor T18, and the gate of the seventeenth transistor T17 is connected to the third scan signal Nscan [n]. The second pole of the eighteenth transistor T18 is connected to the first pole of the twentieth transistor T20 and to the third power supply signal VCT, and the gate of the eighteenth transistor T18 is connected to the Nscan [n-1]_inv scan signal. The second pole of the twentieth transistor T20 is connected to the first pole of the nineteenth transistor T19, and the gate of the twentieth transistor T20 is connected to the second scan signal Nscan [n-1]. The second pole of the nineteenth transistor T19 is connected to the first electrode plate of the capacitor C0, and the gate of the nineteenth transistor T19 is connected to the first scan signal Nscan [n]_inv. The second electrode plate of the capacitor C0 is connected to the fourth power supply signal VCL.

In the embodiment shown in FIG. 3, the second gating circuit 1015 includes a twenty-first transistor T21, a twenty-second transistor T22, a twenty-third transistor T23, . . . , and a twenty-sixth transistor T26.

The first pole of the twenty-first transistor T21 is connected to the first power supply signal VGHN, the gate of the twenty-first transistor T21 is connected to the second pole of the nineteenth transistor T19 and the first electrode plate of the capacitor C0, and the second pole of the twenty-first transistor T21 is connected to the first pole of the twenty-third transistor T23. The first pole of the twenty-second transistor T22 is connected to the first power supply signal VGHN, the gate of the twenty-second transistor T22 is connected to the third scan signal Nscan [n], and the second pole of the twenty-second transistor T22 is connected to the first pole of the twenty-third transistor T23.

The second pole of the twenty-third transistor T23 is connected to the first pole of the twenty-fourth transistor T24, and the gate of the twenty-third transistor T23 is connected to the gate of the twenty-first transistor T21. The second pole of the twenty-fourth transistor T24 is connected to the fifth power supply signal VGL, and the gate of the twenty-fourth transistor T24 is connected to the gate of the twenty-second transistor T22.

The first pole of the twenty-fifth transistor T25 is connected to the first power supply signal VGHN, the second pole of the twenty-fifth transistor T25 is connected to the second pole of the twenty-sixth transistor T26 and to the output signal Nout [n], and the gate of the twenty-fifth transistor T25 is connected to the second pole of the twenty-first transistor T21. The first pole of the twenty-sixth transistor T26 is connected to the fifth power supply signal VGL, the second pole of the twenty-sixth transistor T26 is connected to the second pole of the twenty-fifth transistor T25 and to the output signal Nout [n], and the gate of the twenty-sixth transistor T26 is connected to the gate of the twenty-fifth transistor T25.

The first pole of the M-th transistor mentioned herein refers to the source or drain of the M-th transistor. The second pole of the M-th transistor is different from the first pole of the M-th transistor, and refers to the other of the source and drain of the M-th transistor. Where M is a positive integer, which can be one, two, three, . . . , or twenty-six, etc.

To clarify, FIG. 3 is only one embodiment of the row addressing circuit in the row addressing region 101. Other circuits that can achieve the above functions can also be used.

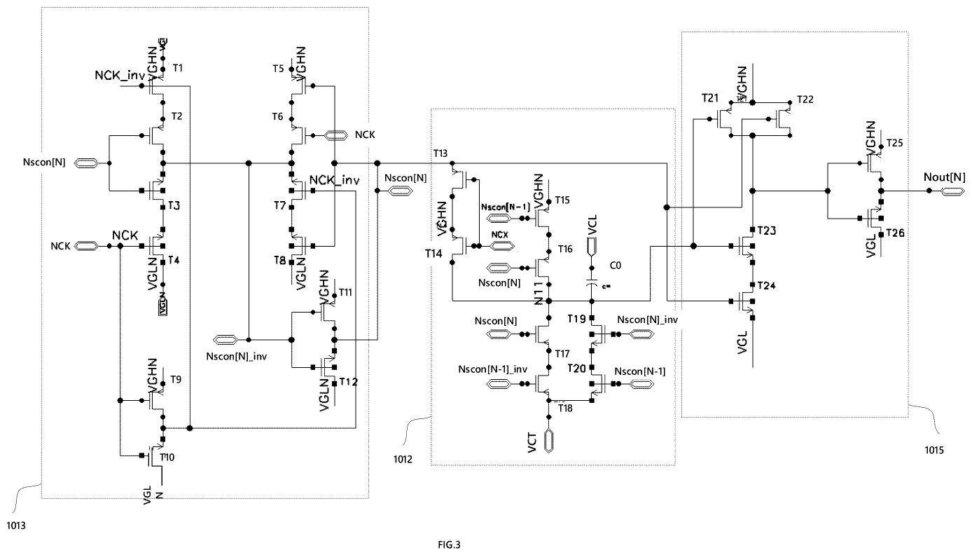

The cross-segmental schematic diagram of the display substrate 100 in the embodiments of the present disclosure can be shown in FIG. 4. As shown in FIG. 4, along the third direction Z (i.e., the stacking direction of each film layer) (where the third direction Z, the first direction X, and the second direction Y are perpendicular to each other), the display substrate 100 sequentially includes a base 20, a driving circuit layer 60, and an organic light-emitting layer. The driving circuit layer 60 includes the row addressing circuit of the row addressing region 101. That is, the row addressing circuit of the row addressing region 101 is set within the driving circuit layer 60. The driving circuit layer 60 further includes pixel circuits located in the normal display region (including the first pixel driving region 102 and the second pixel driving region 104). The pixel circuit is usually composed of a capacitor and multiple thin film transistors, which used to control the light emission of pixels in the first pixel driving region 102 and the second pixel driving region 104. The row addressing circuit of the row addressing region 101 is set on the same layer as the pixel circuit. Since the components of the row addressing region 101 and the pixel circuit are the same, mainly including thin film transistors and capacitors, the row addressing region 101 can be easily synchronously formed with the pixel circuit, which is beneficial for simplifying process steps and reducing production costs.

In some embodiments, referring to FIGS. 1 and 2, the pixel circuit of the first pixel driving region 102, the row addressing circuit of the row addressing region 101, and the pixel circuit of the second pixel driving region 104 are arranged in sequence along the first direction X. The row addressing region 101 mainly extends along the second direction Y. Where the first direction X is the row direction, i.e., the horizontal direction in the figure, and the second direction Y is the column direction, i.e., the vertical direction in the figure.

Since the first pixel driving region 102 and the second pixel driving region 104 are normal display regions, the row addressing region 101 mainly extends along the second direction Y, and the width (approximately only a few pixels to a dozen pixels) of the row addressing region 101 in the first direction X is significantly smaller than the length of the row addressing region 101 in the second direction Y, which is beneficial for increasing the area of the normal display regions.

In some embodiments, the region where the row addressing region 101 is located may emit light like a normal display region. Correspondingly, on the row addressing region 101 are also provided anodes, organic light-emitting materials, and cathodes, with multiple pixels for display. The pixels in the region where the row addressing region 101 is located can be driven by the pixel circuits of the first pixel driving region 102 and/or the second pixel driving region 104 to emit light.

In some embodiments, the base 20 includes or is a flexible substrate 25. The material of the flexible substrate 25 may include one or more of polyimide, polyethylene terephthalate, polycarbonate, or organic resin material. The organic resin material may include epoxy resin, triazine, silicone resin, or polyimide, etc.

In some embodiments, the base 20 includes or is a rigid substrate 23. The rigid substrate 23 may include any one of glass substrate, quartz substrate, sapphire substrate, or ceramic substrate, etc., or the rigid substrate 23 may include any one of semiconductor substrate such as single crystalline semiconductor substrate or polycrystalline semiconductor substrate made of silicon or silicon carbide, or compound semiconductor substrate such as silicon germanium, or SOI (Silicon On Insulator) substrate.

In some embodiments, the base 20 includes both a rigid substrate 23 and a flexible substrate 25, where the flexible substrate 25 is disposed between the rigid substrate 23 and the driving circuit layer 60. Moreover, after the device is manufactured or during the manufacturing process, the rigid substrate 23 can be removed to give the entire device higher flexibility. The rigid substrate 23 mainly serves to support the flexible substrate 25 and the driving circuit layer 60 during the manufacturing process.

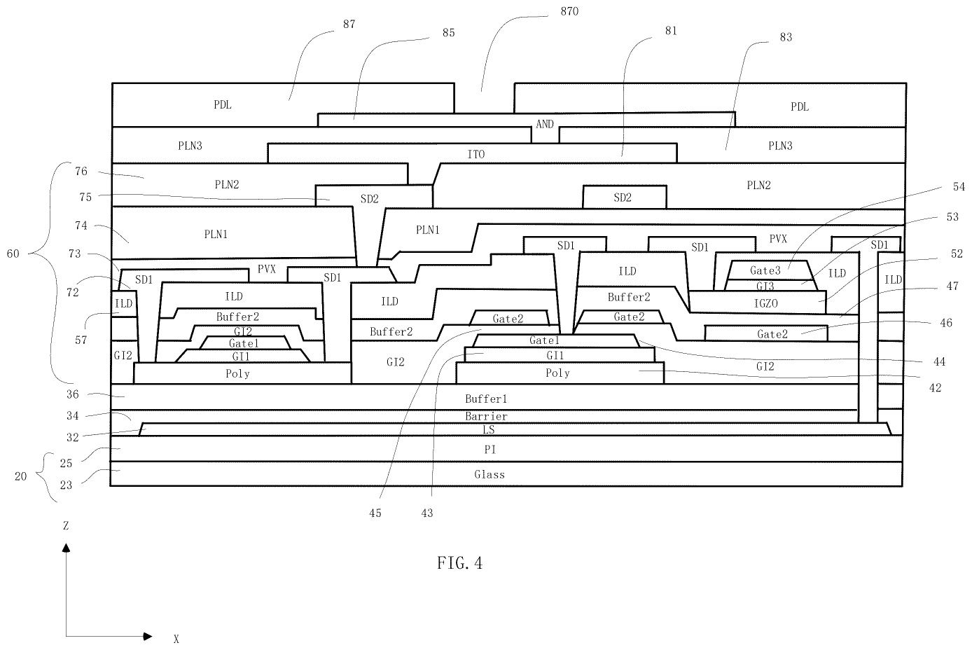

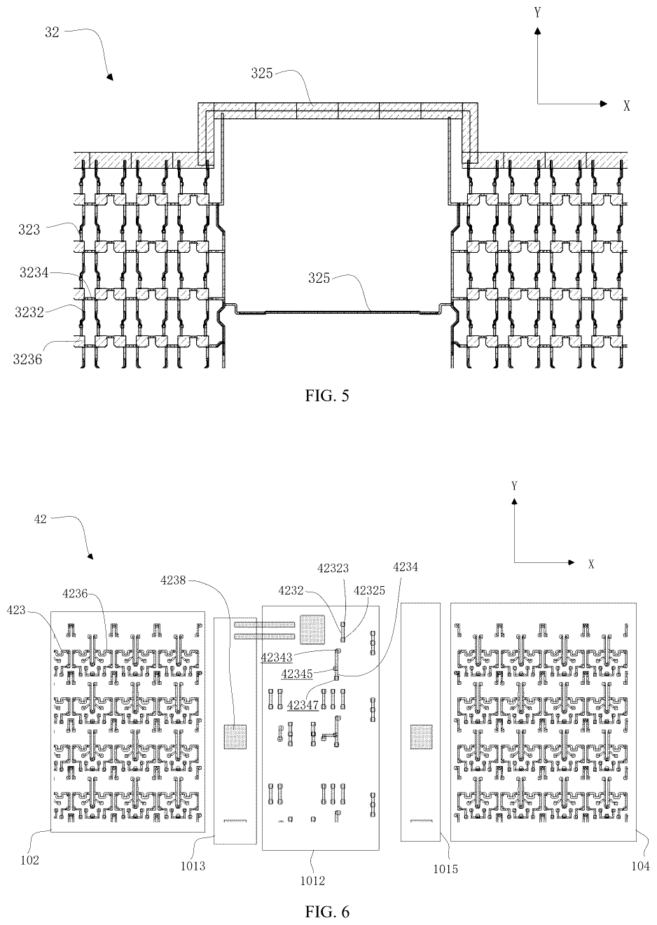

To avoid being affected by external electronic components or external electric fields, a bottom shielding layer 32 can be provided on the front side of the base 20. As shown in FIGS. 4 and 5, the bottom shielding layer 32 may include a shielding pattern 323 and a connecting wire 325. The shielding pattern 323 may include a horizontal shielding line 3234 extending along the first direction X, a vertical shielding line 3232 extending along the second direction Y, and a square shielding block 3236 arranged at the intersection of the horizontal shielding line 3234 and the vertical shielding line 3232. The morphology of the shielding pattern 323 can correspond to the morphology of at least some conductive elements (such as active regions, gate lines, data lines, etc.) within the pixel circuit. The connecting wire 325 is used to electrically connect the various shielding patterns 323 into a whole. The material of the bottom shielding layer 32 can be metal, such as aluminum, copper, silver, etc.

A whole layer of barrier layer 34 can be provided on the bottom shielding layer 32. The material of the barrier layer can be an insulating material such as silicon oxide, silicon nitride, or silicon oxynitride, etc., used to block the entry of water, or oxygen, etc. A whole layer of buffer layer 36 (can be referred to as a first buffer layer 36) can be provided on the barrier layer 34. The material of the buffer layer 36 can be an insulating material such as silicon oxide, silicon nitride, or silicon oxynitride. The buffer layer 36 may have a thick film thickness. The upper surface of the buffer layer 36 is a flat surface. The buffer layer 36 can serve as a flat layer to improve the morphology quality of the film layer formed on the buffer layer 36.

Referring to FIG. 4 and, if necessary, in conjunction with FIG. 6, an active layer 42 (also referred to as the first active layer 42) can be provided on the buffer layer 36. The material of the active layer 42 can be amorphous silicon or polycrystalline silicon, etc. The active layer 42 includes multiple active regions 423, each active region 423 is generally elongated and corresponds to one thin film transistor or multiple electrically connected thin film transistors. For a first type active region 4232 with a simple structure and only corresponding to one thin film transistor, its two ends in the length direction respectively serve as the source region 42323 and the drain region 42325 of the thin film transistor, and the active region between the source region 42323 and the drain region 42325 serves as the channel of the thin film transistor. The second type active region 4234 with complex structure corresponds to two thin film transistors connected in series. The second type active region 4234 is sequentially provided with a first source drain region 42343, a second source drain region 42345, and a third source drain region 42347 along its length direction. Where the first source drain region 42343 and the third source drain region 42347 are located at both ends of the second type active region 4234, and the second source drain region 42345 is located in the middle region of the second type active region 4234. The first source drain region 42343 and the second source drain region 42345 respectively serve as the source and drain regions of a thin film transistor, and the active region between the first source drain region 42343 and the second source drain region 42345 serves as the channel of the thin film transistor. The second source drain region 42345 and the third source drain region 42347 respectively serve as the source and drain regions of another thin film transistor, and the active region between the second source drain region 42345 and the third source drain region 42347 serves as the channel of the another thin film transistor. The more complex third type active region 4236 is composed of multiple first type active regions 4232 and second type active regions 4234 connected together. This makes the third type active region 4236 correspond to a structure of more thin film transistors connected in parallel and series. A portion of the active region within the third type active region 4236 extends along the first direction X, and another portion of the active region extends along the second direction Y. This results in the third type active region 4236 occupying a larger size in both the first direction X and the second direction Y.

In addition to the strip-shaped active region, there is also a block-shaped active region 4238. The sizes of the block-shaped active region 4238 in the first direction X and the second direction Y is basically the same.

The active layer 42 is not only set in the normal display region, but also in the row addressing region 101. Because the scanning drive circuit 1012, the first gating circuit 1013, and the second gating circuit 1015 all include thin film transistors, the active regions corresponding to the thin film transistors are also synchronously distributed in the regions where the scanning drive circuit 1012, the first gating circuit 1013, and the second gating circuit 1015 are located.

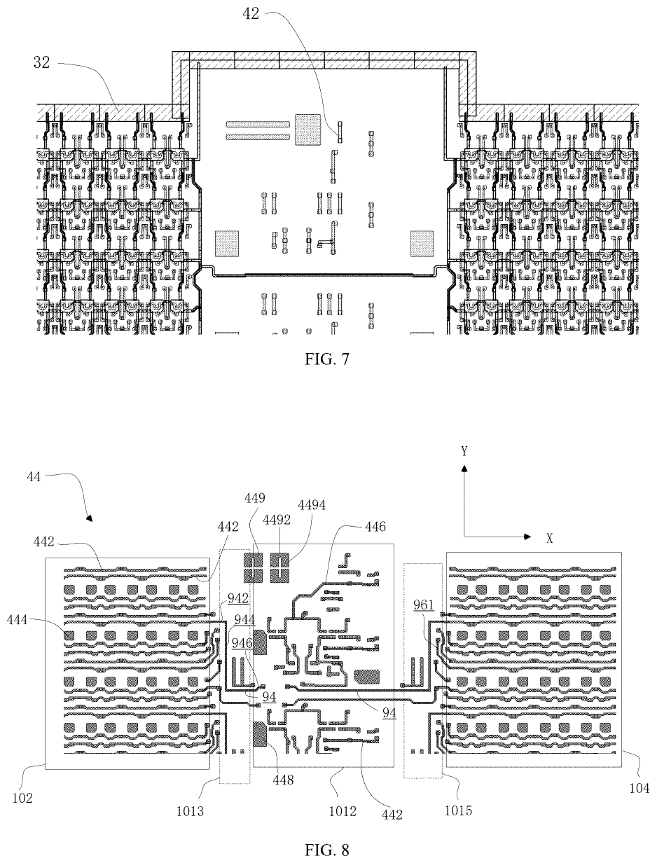

The view of the overlay of the production layout of the active layer 42 and the production layout of the bottom shielding layer 32 is shown in FIG. 7. The main region of the active layer 42 in the normal display region has been shielded by the bottom shielding layer 32. The active layer 42 within the row addressing region 101 may not be shielded by the bottom shielding layer 32.

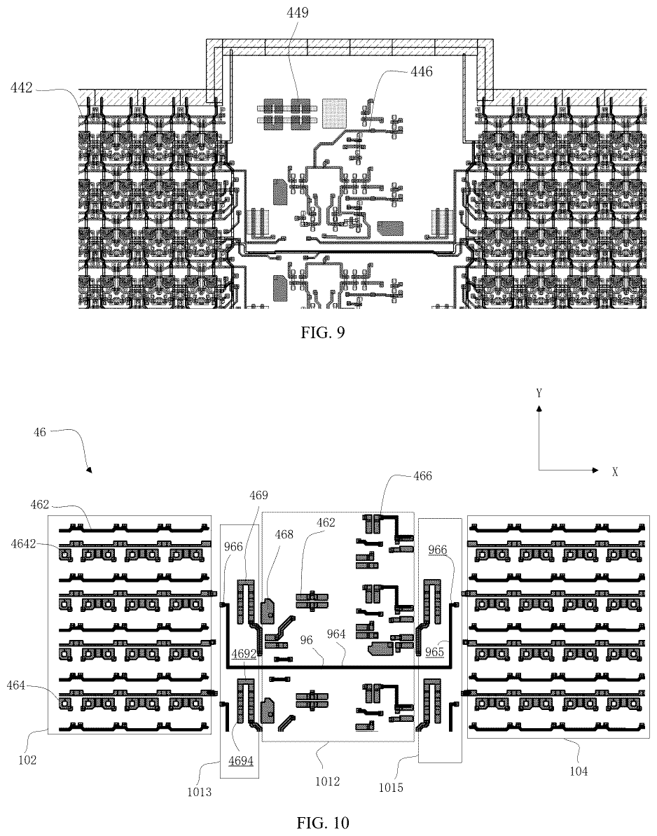

Referring to FIG. 4, and in conjunction with FIGS. 8 and 9, a gate insulating layer 43 (also known as the first gate insulating layer 43) and a gate layer 44 (also known as the first gate layer 44) can be provided on the active layer 42. The gate insulating layer 43 can be a complete layer or have a similar morphology and pattern to the gate layer 44, as long as it can effectively isolate the gate layer 44 from the active layer 42. The material of the gate insulating layer 43 can be silicon oxide, silicon nitride, or silicon oxynitride. The material of the gate layer 44 can be metal material such as aluminum, copper, or silver, etc.

The gate layer 44 includes a first type gate line 442 extending along the first direction X and multiple gate pattern blocks 444 in a normal display region (such as the first pixel driving region 102 and the second pixel driving region 104). Each gate pattern block 444 is roughly block-shaped, and several gate pattern blocks 444 are arranged in a row along the first direction X. The region directly below the first type gate line 442 corresponds to the channel of the active layer 42.

The gate layer 44 includes a first type gate line 442 extending along the first direction X, a second type gate line 446 extending along both the first direction X and the second direction Y, multiple block-shaped gate pattern blocks 448, and multiple U-shaped third type gate lines 449 in the regions of the first gating circuit 1013, the scan drive circuit 1012, and the second gating circuit 1015. Each of the third type gate lines 449 includes a horizontal connecting line 4492 extending along the first direction X, and two vertical gate portions 4494 respectively arranged at both ends of the horizontal connecting line 4492. The two vertical gate portions 4494 are parallelly arranged and spaced apart from each other. Two vertical gate portions 4494 within the same third type gate line 449 are located directly above the same active region. Similarly, the region directly below the first type gate line 442 and the second type gate line 446 corresponds to the channel of the active layer 42.

Since the row addressing region 101 (especially the region where the scan driving circuit 1012 is located) is located between adjacent display regions, all or at least one part of the gate lines need to bypass the row addressing region 101 to connect with the gate lines of the other display region. Therefore, a gate connecting line 94 (also known as the first gate connecting line 94) can be set in the gate layer 44 to connect the gate lines on both sides of the row addressing region 101 and avoid affecting the arrangement of components in the row addressing region 101 as much as possible. Connecting the gate lines on both sides through the gate connecting line is beneficial for maintaining consistency in ESD (electrostatic discharge) protection of the entire device.

The gate connecting line 94 may include a gate connecting end 942 connected to the gate line, an away gate end 946 located in the scan driving circuit 1012 region (or row addressing region 101) and away from the gate line, and a winding line segment 944 located between the gate connecting end 942 and the away gate end 946 and connecting the gate connecting end 942 and the away gate end. The gate connecting end 942 and the away gate end 946 can extend along or mainly along the first direction X. The winding segment 944 may extend along or primarily along the second direction Y. Then, by setting connecting holes between the film layers and transferring of the connecting lines or connecting patterns located in other film layers (such as gate layer 46 or gate layer 54), the gate connecting line 94 can conduct with other gate connecting lines, thereby achieving connections between the gate lines.

Another type of gate connecting line 961 (also known as a second gate connecting line 961) can be provided within the gate layer 44. One end of the gate connecting line 961 is connected to the gate line, and the other end of the gate connecting line 961 does not extend to the scan driving circuit 1012 region but only slightly extends into the row addressing region 101 or to the region near the row addressing region 101, and the gate connecting line 961 mainly extends along the second direction Y. Then, by setting connecting holes between the film layers and transferring of the connecting lines or connecting patterns located in other film layers (such as gate layer 46 or gate layer 54), the gate connecting line 961 can conduct with other gate connecting lines, thereby achieving connections between the gate lines. The connecting line or connecting pattern connected to the gate connecting line 961 should include a portion that spans the scanning drive circuit 1012 region, so as to better assist the gate connecting line 961 in achieving wire wrapping in the scanning drive circuit 1012 region.

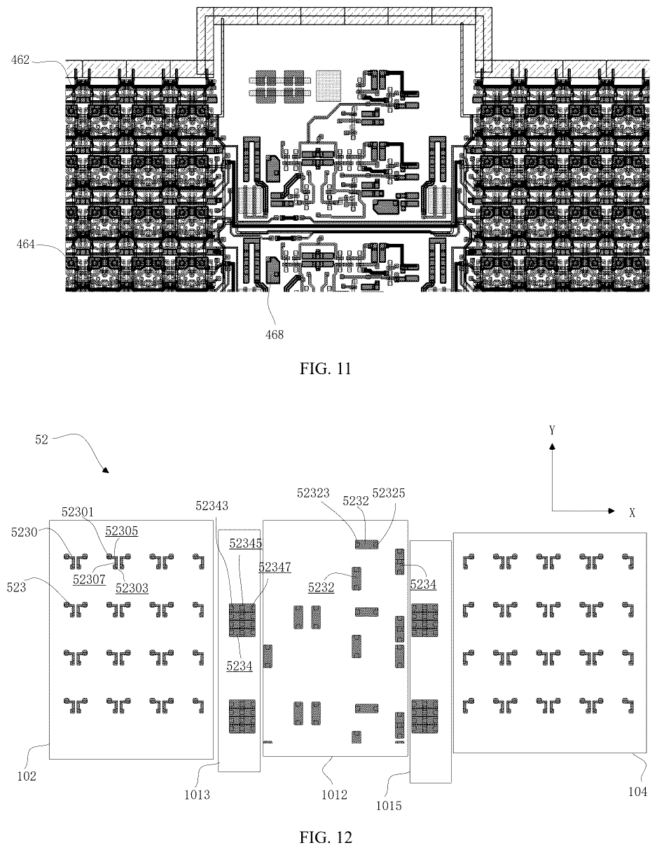

Referring to FIGS. 10 and 11, and in conjunction with FIG. 4, a gate insulating layer 45 (also known as the second gate insulating layer 45) and a gate layer 46 (also known as the second gate layer 46) can be provided on the gate layer 44. The gate insulating layer 45 can be a complete layer or have a similar morphology and pattern to the gate layer 46, as long as it can effectively isolate the gate layer 46 from the first gate layer 44 below. The material of the gate insulating layer 45 can be silicon oxide, silicon nitride, or silicon oxynitride. The material of the gate layer 46 can be metal material such as aluminum, copper, or silver, etc.

The gate layer 46 includes a fourth type gate line 462 extending along the first direction X and multiple gate pattern blocks 464 in a normal display region (such as the first pixel driving region 102 and the second pixel driving region 104). The fourth type gate line 462 is located directly above the first type gate line 442 and forms a capacitor with the first type gate line 442. Each gate pattern block 464 is roughly block-shaped, and several gate pattern blocks 464 are arranged in a row along the first direction X. The gate pattern block 464 is located directly above the corresponding gate pattern block 444 and forms a capacitor with the corresponding gate pattern block 444. The interior of the gate pattern block 464 is provided with a relief hole 4642, and through the relief hole 4642, the conductive film layer or electronic component above can communicate with the gate pattern block 444 below.

The gate layer 46 in the row addressing region 101 includes a fourth type gate line 462 extending along the first direction X, a fifth type gate line 466 extending along both the first direction X and the second direction Y, multiple block-shaped gate pattern blocks 468, and multiple U-shaped sixth type gate lines 469. Each of the sixth type gate lines 469 includes a horizontal connecting line 4692 extending along the first direction X, and two vertical gate portions 4694 respectively arranged at both ends of the horizontal connecting line 4692. The two vertical gate portions 4694 are parallelly arranged and spaced apart from each other. The gate pattern block 468 is located directly above the corresponding gate pattern block 448. The corresponding gate pattern block 468 and gate pattern block 448 form a capacitor.

A gate connecting line 96 (also known as a third gate connecting line 96) can be provided within the gate layer 46 to connect the gate lines on both sides of the row addressing region 101 (such as the gate lines located within the gate layer 44).

The gate connecting line 96 may include a middle connecting segment 964 located in the middle region of the scan driving circuit 1012 and extending along the first direction X to both sides. The gate connecting line 96 may further include two near gate ends 966, which are located on opposite sides of the gate connecting line 96 along the first direction X. The near gate end 966 can be connected to a gate line in another film layer (such as gate layer 44 or gate layer 54) through a connecting hole set between the film layers. The gate connecting line 96 may further include a vertical segment 965 that mainly extends along the second direction Y and is connected between the middle connecting segment 964 and the near gate end 966.

In some embodiments, the near gate end 966 of the gate connecting line 96 can be connected to the gate connecting line 961 within the gate layer 44 through a connecting hole provided between the film layers, thereby achieving communication between the gate lines within the gate layer 44.

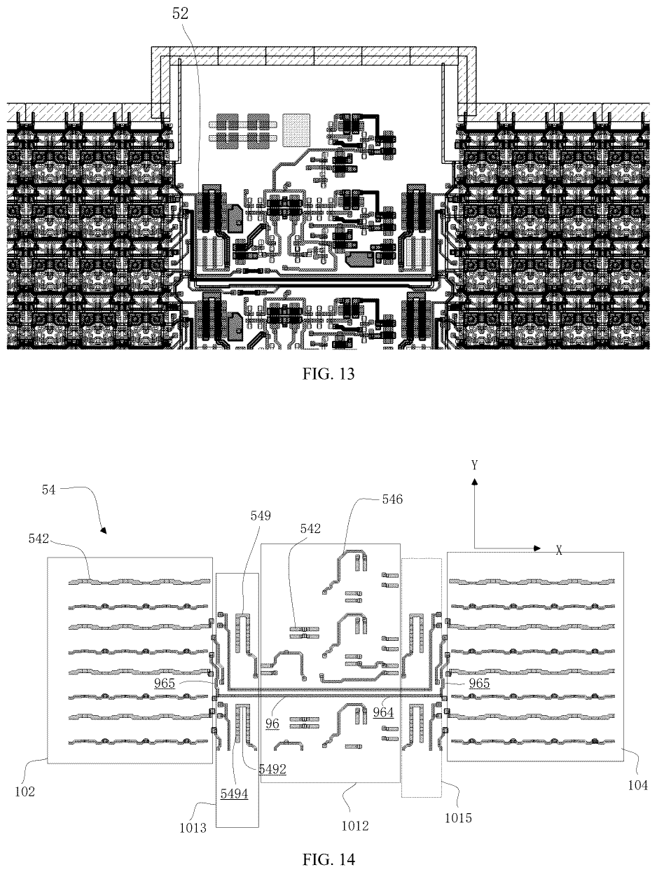

Referring to FIGS. 4, 12, and 13, a whole layer of buffer layer 47 (second buffer layer 47) can be provided on the gate layer 46. The material of the buffer layer 47 can be an insulating material such as silicon oxide, silicon nitride, or silicon oxynitride. An active layer 52 (also known as a second active layer 52) can be provided on the buffer layer 47. The material of the active layer 52 may be metal oxide, such as amorphous IGZO (Indium Gallium Zinc Oxide). The active layer 52 includes multiple active regions 523. Each active region 523 generally extends in a strip shape, and corresponds to one thin film transistor or multiple electrically connected thin film transistors. For the first type active region 5230 or 5232 with a simple structure and corresponding to only one thin film transistor, the two ends in the length direction respectively serve as the source region 52301 or 52323 and the drain region 52303 or 52325 of the thin film transistor. The active region between the source region 52301 or 52323 and the drain region 52303 or 52325 serves as the channel of the thin film transistor. The second type active region 5234 with complex structure corresponds to two thin film transistors connected in series. The second type active region 5234 is sequentially provided with a first source drain region 52343, a second source drain region 52345, and a third source drain region 52347 along its length direction. Where the first source drain region 52343 and the third source drain region 52347 are located at both ends of the second type active region 5234, and the second source drain region 52345 is located in the middle region of the second type active region 5234. The first source drain region 52343 and the second source drain region 52345 respectively serve as the source and drain regions of a thin film transistor, and the active region between the first source drain region 52343 and the second source drain region 52345 serves as the channel of the thin film transistor. The second source drain region 52345 and the third source drain region 52347 respectively serve as the source and drain regions of another thin film transistor, and the active region between the second source drain region 52345 and the third source drain region 52347 serves as the channel of the another thin film transistor.

The active layer 52 is not only set in the normal display region, but also in the row addressing region 101. Because the scanning drive circuit 1012, the first gating circuit 1013, and the second gating circuit 1015 all include thin film transistors, the active regions corresponding to the thin film transistors are also synchronously distributed in the regions where the scanning drive circuit 1012, the first gating circuit 1013, and the second gating circuit 1015 are located.

The channel of the first type active region 5230 set in the normal display region includes both the first connection region 52305 extending along the first direction X and the second connection region 52307 extending along the second direction Y. One end of the first connection region 52305 is connected to the source region 52301, and the other end is connected to the second connection region 52307. One end of the second connection region 52307 is connected to the first connection region 52305, and the other end is connected to the drain region 52303.

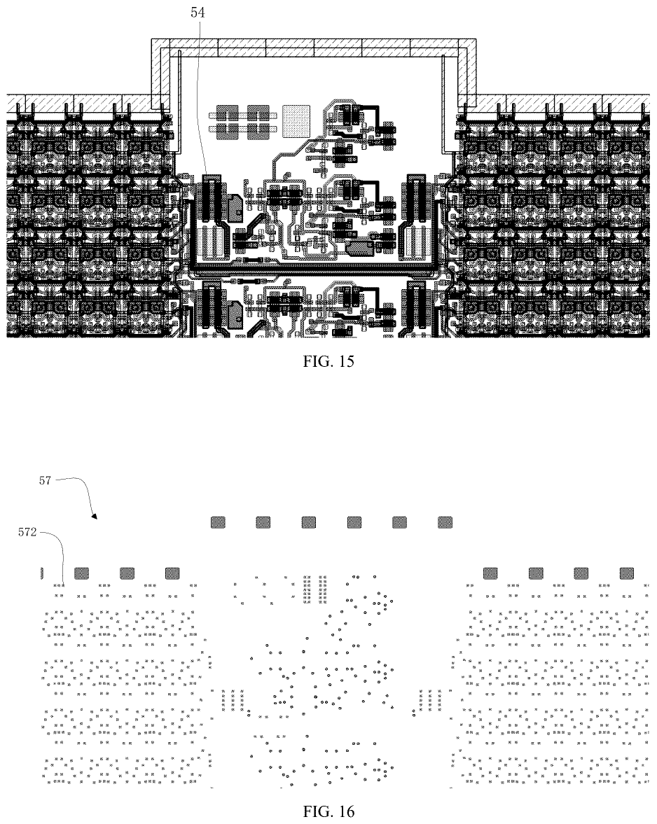

Referring to FIGS. 4 and 14-15, a gate insulating layer 53 (also known as the third gate insulating layer 53) and a gate layer 54 (also known as the third gate layer 54) can be provided on the active layer 52. The gate insulating layer 53 can be a complete layer or have a similar morphology and pattern to the gate layer 54, as long as it can effectively isolate the gate layer 54 from the active layer 52. The material of the gate insulating layer 53 can be silicon oxide, silicon nitride, or silicon oxynitride. The material of the gate layer 54 can be metal material such as aluminum, copper, or silver, etc.

The gate layer 54 includes a first type gate line 542 extending along the first direction X in the normal display region. The region directly below the first type gate line 542 corresponds to the channel of the active layer 52.

The gate layer 54 in the row addressing region 101 includes a first type gate line 542 extending along the first direction X, a second type gate line 546 extending along both the first direction X and the second direction Y, and multiple U-shaped third type gate lines 549. Each of the third type gate lines 549 includes a horizontal connecting line 5492 extending along the first direction X, and two vertical gate portions 5494 respectively arranged at both ends of the horizontal connecting line 5492. The two vertical gate portions 5494 are parallelly arranged and spaced apart from each other. Two vertical gate portions 5494 within the same third type gate line 549 are located directly above the same active region. Similarly, the region directly below the first type gate line 542 and the second type gate line 546 corresponds to the channel of the active layer 52.

The gate layer 54 is located directly above the gate layer 46 in the normal display region and a part of the region where the scan driving circuit 1012 is located. That is, there is an overlapping region between the gate layer 54 and the gate layer 46 in the normal display region and the scan driving circuit 1012 region, and the overlapping region form a capacitor.

A gate connecting line 96 (also known as a third gate connecting line 96) can also be set in the gate layer 54 to connect the gate lines on both sides of the row addressing region 101 (such as the gate lines located in the gate layer 44 or gate layer 46).

The gate connecting line 96 located within the gate layer 54 may also include a middle connecting segment 964 located in the middle region of the row addressing region 101 and extending along the first direction X on both sides. The gate connecting line 96 may further include two near gate ends 966, which are located on opposite sides of the gate connecting line 96 along the first direction X. The near gate end 966 can be connected to a gate line in another film layer (such as gate layer 44 or gate layer 54) through a connecting hole set between the film layers. The gate connecting line 96 may further include a vertical segment 965 that mainly extends along the second direction Y and is connected between the middle connecting segment 964 and the near gate end 966.

In some embodiments, the near gate end 966 of the gate connecting line 96 can be connected to the gate connecting line 961 within the gate layer 44 through a connecting hole provided between the film layers, thereby achieving communication between the gate lines within the gate layer 44.

At present, some of the better display panels (such as LTPO (low-temperature polycrystalline oxide) display panels) typically include two types of thin-film transistors in their pixel circuits, namely N-type thin-film transistors and P-type thin-film transistors. The first active layer 42 and the first gate layer 44 can be used to manufacture the P-type thin film transistor. The second active layer 52 and the third gate layer 54 mentioned above can be used to manufacture the N-type thin film transistor. A portion of the metal pattern within the second gate layer 46 can be used as connecting wires to achieve electrical connections between other components within the film layer. A portion of the metal pattern within the second gate layer 46 may be arranged opposite to the corresponding portion within the first gate layer 44, to form a capacitor, and another portion of the metal pattern within the second gate layer 46 may be arranged opposite to a corresponding portion within the third gate layer 54, to form a capacitor.

Referring to FIGS. 4 and 16-18, an interlayer dielectric layer 57 can be provided on the gate layer 54, and a first source-drain electrode layer 72 can be formed above the interlayer dielectric layer 57. The interlayer dielectric layer 57 may be a whole layer. The material of the interlayer dielectric layer 57 can be insulating material such as silicon oxide, silicon nitride, or silicon oxynitride.

Before forming the first source-drain electrode layer 72, multiple connecting holes 572 can be formed in the interlayer dielectric layer 57 using a local etching process. The layout of connecting holes 572 is shown in FIG. 16.

When forming the first source-drain electrode layer 72, the material of the first source-drain electrode layer 72 will be simultaneously filled into the connecting hole 572, such that the first source-drain electrode layer 72 is electrically connected to the film layer (such as the active layer 52) below. The first source-drain electrode layer 72 or at least one portion of the first source-drain electrode layer 72 can be regarded as a wiring pattern or redistribution layer. The material of the first source-drain electrode layer 72 can be metal conductive material such as aluminum, copper, or silver, etc.

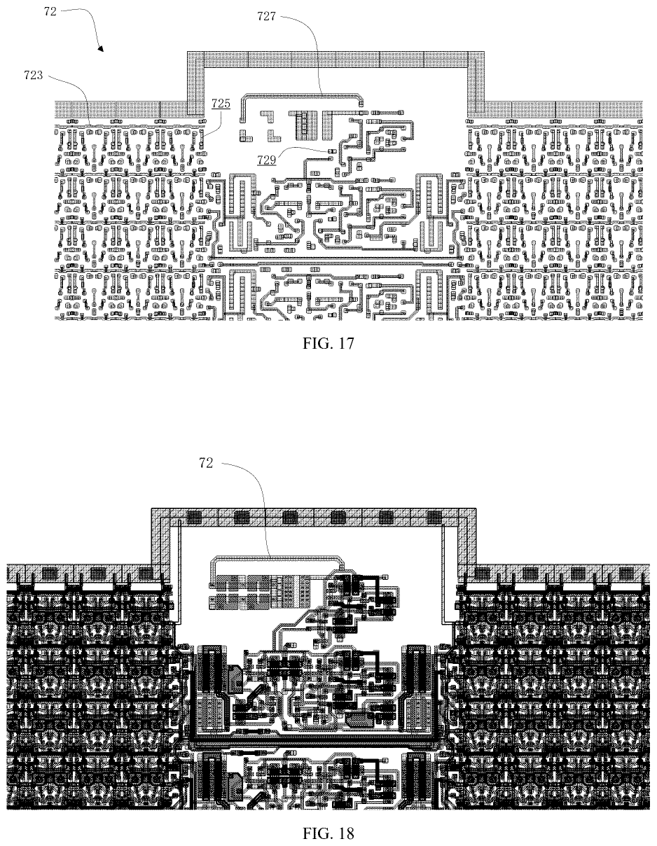

As shown in FIGS. 17 and 18, the first source-drain electrode layer 72 may include a first wire 723 extending along the first direction X, a second wire 725 extending along the second direction Y, a third wire 727 extending both along the first direction X and the second direction Y, and a fourth conductive block 729 in the form of a dot or a block.

Referring to FIGS. 4 and 19-21, a passivation layer 73 can be provided on the first source-drain electrode layer 72, a planarization layer 74 (also known as the first planarization layer 74) can be formed above the passivation layer 73, and a second source-drain electrode layer 75 can be formed above the planarization layer 74. Where the passivation layer 73 may be a whole layer. The material of the passivation layer 73 can be insulating material such as silicon oxide, silicon nitride, or silicon oxynitride. The planarization layer 74 may be a whole layer. The upper surface of the planarization layer 74 may be a flat surface. The material of the planarization layer 74 can be silicon oxide, silicon nitride, silicon oxynitride, or organic material.

Before forming the second source-drain electrode layer 75, a local etching process can be used to form multiple connecting holes 732 and 742 in the planarization layer 74 and passivation layer 73. The layout of connecting holes 732 and 742 is shown in FIG. 19.

When forming the second source-drain electrode layer 75, the material of the second source-drain electrode layer 75 will be simultaneously filled into the connecting holes 732 and 742, so that the second source-drain electrode layer 75 is electrically connected to the underlying film layer (such as the first source-drain electrode layer 72). The material of the second source-drain electrode layer 75 can be metal conductive material such as aluminum, copper, or silver, etc.

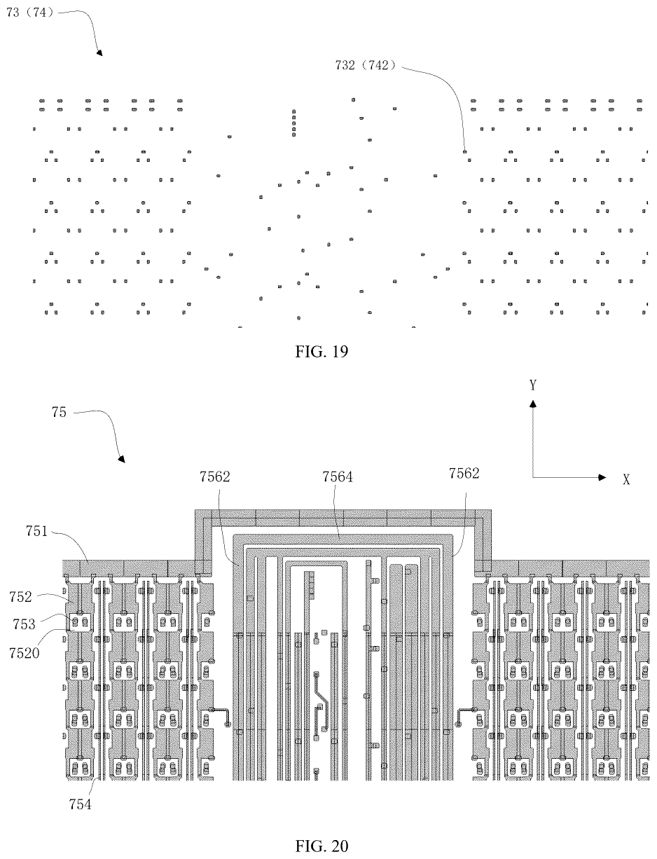

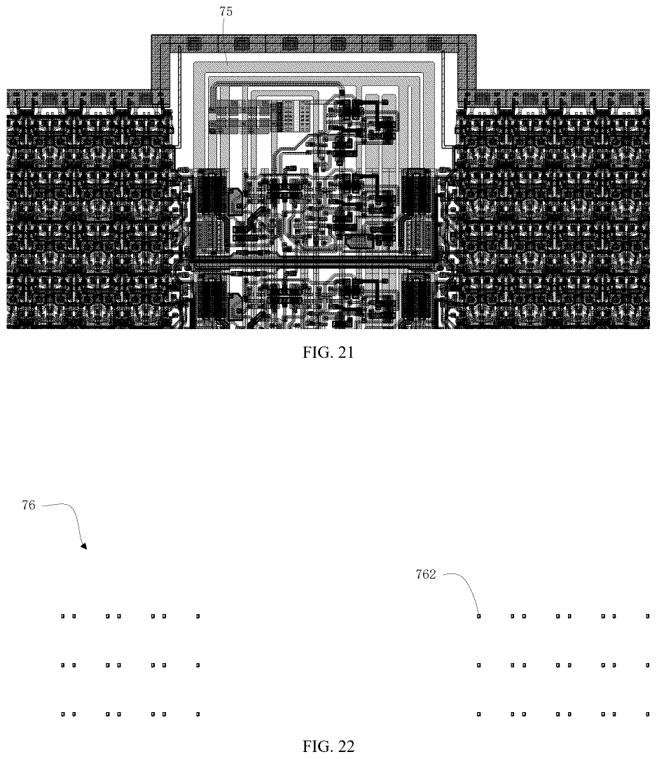

As shown in FIGS. 20 and 21, the second source-drain electrode layer 75 may include a first data line 752 extending along the second direction Y. There are multiple avoidance holes 7520 arranged along the second direction Y in the first data line 752. A wire block 753 is provided inside the avoidance hole 7520. The first data lines 752 set in the first gating circuit 1013 and the second gating circuit 1015 can be connected as a whole through a conductive line 751. The conductive line 751 extends as a whole along the first direction X.

The second source-drain electrode layer 75 may also include a second data line 754 extending along the second direction Y. The width of the second data line 754 is significantly smaller than that of the first data line 752.

The second source-drain electrode layer 75 may also include a third data line 7562 located within the scanning drive circuit 1012 region. Each of the third data lines 7562 extends along the second direction Y. Two or more third data lines 7562 are connected through a conductive line 7564. The conductive line 7564 extends along the first direction X.

Referring to FIGS. 4 and 22-23, a planarization layer 76 (also known as the second planarization layer 76) can be provided above the second source-drain electrode layer 75, and a transparent electrode layer 81 can be formed above the planarization layer 76. The planarization layer 76 may be a whole layer. The upper surface of the planarization layer 76 may be a flat surface. The material of the planarization layer 76 can be silicon oxide, silicon nitride, silicon oxynitride, or organic material.

Before the transparent electrode layer 81 is formed, multiple connecting holes 762 can be formed within the planarization layer 76 using a local etching process. The layout of connecting holes 762 is shown in FIG. 22.

When forming the transparent electrode layer 81, the material of the transparent electrode layer 81 will be simultaneously filled into the connecting hole 762, such that the transparent electrode layer 81 is electrically connected to the underlying film layer (such as the second source-drain electrode layer 75). The material of the transparent electrode layer 81 can be ITO (indium tin oxide).

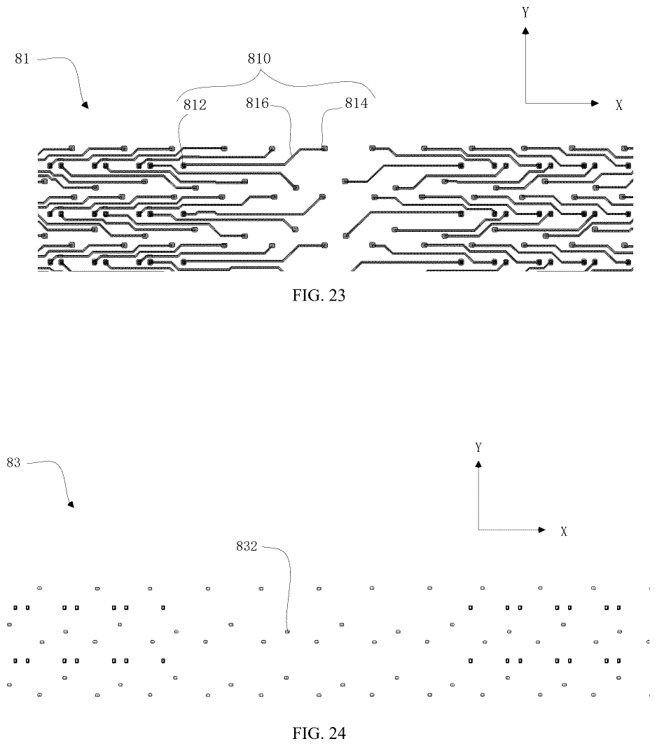

As shown in FIG. 23, the transparent electrode layer 81 may include multiple electrode strips 810. The electrode strip 810 includes a first terminal 812, a second terminal 814, and an electrode body 816 located between the first terminal 812 and the second terminal 814. The first terminal 812 and the second terminal 814 are located at both ends of the electrode strip 810 in the first direction X. The electrode body 816 generally extends along the first direction X.

Referring to FIGS. 4 and 24-25, a planarization layer 83 (also known as the third planarization layer 83) can be provided above the transparent electrode layer 81, and an anode layer 85 can be formed above the planarization layer 83. The planarization layer 83 may be a whole layer. The upper surface of the planarization layer 83 may be a flat surface. The material of the planarization layer 83 can be silicon oxide, silicon nitride, silicon oxynitride, or organic material.

Before forming the anode layer 85, multiple connecting holes 832 can be formed within the planarization layer 83 using a local etching process. The layout of connecting holes 832 is shown in FIG. 24.

When forming the anode layer 85, the material of the anode layer 85 will be simultaneously filled into the connecting hole 832, such that the anode layer 85 is electrically connected to the underlying film layer (such as the transparent electrode layer 81). The material of the anode layer 85 can be metal material such as aluminum, copper, or silver, or transparent conductive material such as indium tin oxide (ITO) or indium zinc oxide.

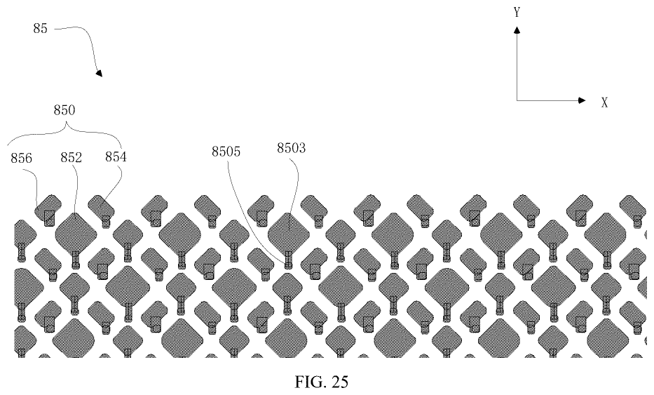

As shown in FIG. 25, the anode layer 85 may include multiple anode patterns 850. Each anode pattern 850 can correspond to a sub-pixel. The anode patterns 850 can have multiple types, including a first anode pattern 852 for the first sub-pixel, a second anode pattern 854 for the second sub-pixel, and a third anode pattern 856 for the third sub-pixel. Where the first sub-pixel, the second sub-pixel, and the third sub-pixel are respectively used to emit light of different colors. For example, the first sub-pixel can be used to emit red light, the second sub-pixel can be used to emit green light, and the third sub-pixel can be used to emit blue light.

Each anode pattern 850 may include a roughly square anode region 8503 and a wiring region 8505 connected to the anode region 8503. The wiring region 8505 is connected to the edge of the anode region 8503.

Referring to FIG. 4, a pixel limiting layer 87 can be provided on the anode layer 85. Multiple grooves 870 are provided within the pixel defining layer 87, with each groove 870 exposing an anode pattern 850. Subsequent organic luminescent materials (or organic luminescent layers) can be filled into the trench 870.

The first gating circuit 1013 can be designed in the form of a long strip, and a length of the first gating circuit 1013 in the second direction Y is significantly greater than a length of the first gating circuit 1013 in the first direction X. Reducing the length of the first gating circuit 1013 in the first direction X is beneficial for increasing the area of the normal display region. In some embodiments, the length of the first gating circuit 1013 in the second direction Y is greater than twice, three times, four times, or five times the length of the first gating circuit 1013 in the first direction X. As shown in FIG. 3, the length of the first gating circuit 1013 in the first direction X can be reduced by mainly arranging the thin film transistors in the first gating circuit 1013 along the second direction Y.

The second gating circuit 1015 can be designed in a long strip shape, and the length of the second gating circuit 1015 in the second direction Y is significantly greater than the length of the second gating circuit 1015 in the first direction X. Reducing the length of the second gating circuit 1015 in the first direction X is beneficial for increasing the area of the normal display region. In some embodiments, the length of the second gating circuit 1015 in the second direction Y is greater than twice, three times, four times, or five times the length of the second gating circuit 1015 in the first direction X. As shown in FIG. 3, the length of the second gating circuit 1015 in the first direction X can be reduced by mainly arranging the thin film transistors in the second gating circuit 1015 along the second direction Y.

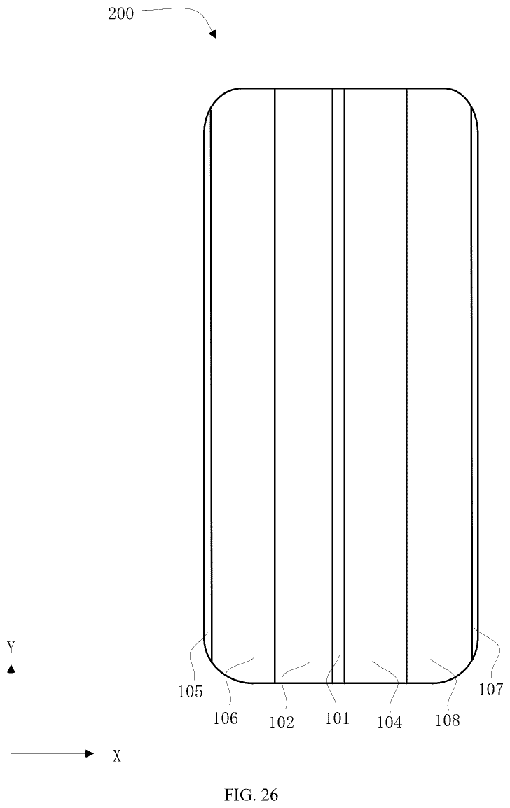

Another embodiment of the present disclosure provides a display substrate as shown in FIG. 26. As shown in FIG. 26, the display base 200 includes:
a base;
a row addressing region 101 (also referred to as the first row addressing region 101), located on the substrate and provided with a row addressing circuit;
a first pixel driving region 102, provided on the base and located on one side of the row addressing region 101, where the first pixel driving region 102 is provided with a pixel circuit;
a second pixel driving region 104, located on the base and on the other side of the row addressing region 101, where the second pixel driving region 104 is provided with a pixel circuit, and the row addressing region 101 is located between the first pixel driving region 102 and the second pixel driving region 104; where the refresh rate of pixels in the first pixel driving region 102 and the refresh rate of pixels in the second pixel driving region 104 are independently controlled by the row addressing circuit of the row addressing region 101;
a row addressing region 105 (also referred to as the second row addressing region 105), provided on the base, and provided with a second row addressing circuit, where the row addressing region 105 is located at one edge of the display base 200; and
a third pixel driving region 106, provided on the substrate and located between the row addressing region 105 and the first pixel driving region 102, where the third pixel driving region 106 is provided with a pixel circuit;
where the second row addressing circuit includes:
a second scan driving circuit;
a third gating circuit 106 between the second scan driving circuit and the third pixel driving region, where the third gating circuit 106 connects the second scan driving circuit and a pixel circuit in the third pixel driving region.

The above settings enable the refresh rate of pixels in the third pixel driving region 106 to be controlled by the second row addressing circuit of the row addressing region 105.

By further setting a second row addressing region and a third pixel driving region at one edge of the display substrate, the refresh rates of the first pixel driving region, the second pixel driving region, and the third pixel driving region located in different regions can be relatively independently adjusted, that is, different regions different frequencies is achieved, which is conducive to reducing display power consumption.

In some embodiments, the structure and manufacturing method of the row addressing region 105 are the same as those of the row addressing region 101.

In some embodiments, the display substrate 200 further includes:
a row addressing region 107 (also referred to as the third row addressing region 107), located on the substrate, and provided with a third row addressing circuit, where the row addressing region 107 is located on the other edge of the display base 200; and
a fourth pixel driving region 108, provided on the substrate, provided with pixel circuits, and located between the second pixel driving region 104 and the row addressing region 107;
where the third row addressing circuit includes:
a third scan driving circuit;
a fourth gating circuit 108 between the third scan driving circuit and the fourth pixel driving region, where the fourth gating circuit 108 connects the third scan driving circuit and a pixel circuit in the fourth pixel driving region.

The above settings enable the refresh rate of pixels in the fourth pixel driving region 108 to be controlled by the third row addressing circuit of the row addressing region 107.

By further setting a third row addressing region and a fourth pixel driving region at the other edge of the display substrate, the refresh rates of the first pixel driving region, the second pixel driving region, the third pixel driving region, and the fourth pixel driving region located in different regions can be relatively independently adjusted, that is, different regions different frequencies is achieved, which is conducive to reducing display power consumption.

In some embodiments, the structure and manufacturing method of the row addressing region 107 are the same as those of the row addressing region 101.

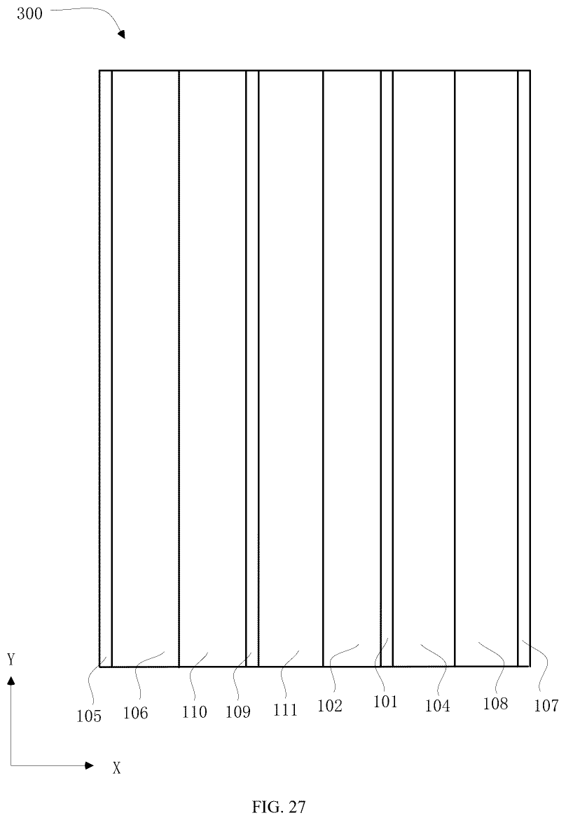

Another embodiment of the present disclosure provides a display substrate as shown in FIG. 27. As shown in FIG. 27, the display base 300 includes:
a base (not shown in the figure);
a row addressing region 101 (also referred to as the first row addressing region 101), located on the substrate and provided with a row addressing circuit;
a first pixel driving region 102, provided on the base and located on one side of the row addressing region 101;
a second pixel driving region 104, located on the base and on the other side of the row addressing region 101, where the row addressing region 101 is located between the first pixel driving region 102 and the second pixel driving region 104; where the refresh rate of the first pixel driving region 102 and the refresh rate of the second pixel driving region 104 are independently controlled by the row addressing circuit of the row addressing region 101;
a row addressing region 105 (also referred to as the second row addressing region 105), provided on the base, and provided with a second row addressing circuit, where row addressing region 105 is located at one edge of the display base 200; and
a third pixel driving region 106, set on the base and located between the row addressing region 105 and the first pixel driving region 102; where the refresh rate of pixels in the third pixel driving region 106 is controlled by the second row addressing circuit of the row addressing region 105;
a row addressing region 107 (also referred to as the third row addressing region 107), located on the substrate, and provided with a third row addressing circuit, where the row addressing region 107 is located on the other edge of the display base 200; and
a fourth pixel driving region 108, set on the base and located between the second pixel driving region 104 and the row addressing region 107; where the refresh rate of pixels in the fourth pixel driving region 108 is controlled by the third row addressing circuit of the row addressing region 107;
a row addressing region 109 (also referred to as the fourth row addressing region 109), set on the base, and provided with a fourth row addressing circuit;
a fifth pixel driving region 110, set on the base and located between the row addressing region 109 and the third pixel driving region 106;
a sixth pixel driving region 111, set on the base and located between the row addressing region 109 and the first pixel driving region 102;
where the fourth row addressing circuit includes:
a fourth scan driving circuit;
a fifth gating circuit between the fourth scan driving circuit and the fifth pixel driving region 110, where the fifth gating circuit connects the fourth scan driving circuit and a pixel circuit in the fifth pixel driving region 110.
a sixth gating circuit between the fourth scan driving circuit and the sixth pixel driving region 111, where the sixth gating circuit connects the fourth scan driving circuit and a pixel circuit in the sixth pixel driving region 111.

The above settings enable the refresh rate of pixels in the fifth pixel driving region 110 and the refresh rate of pixels in the sixth pixel driving region 111 to be independently controlled by the fourth row addressing circuit of the row addressing region 109.

By further setting up another row addressing region 109, a fifth pixel driving region 110 and a sixth pixel driving region 111 within the display substrate, the refresh rates of the first pixel driving region, second pixel driving region, third pixel driving region, fourth pixel driving region, fifth pixel driving region, and sixth pixel driving region located in different regions can be relatively independently adjusted, thereby achieving different regions different frequencies and reducing display power consumption.

In some embodiments, the structure and manufacturing method of the row addressing region 109 are the same as those of the row addressing region 101.

In some embodiments, the number of pixels in each row of the first pixel driving region 102 is equal to the number of pixels in each row of the second pixel driving region 104. The term ‘the number of . . . is equal to’ mentioned in the text includes both a situation where the number of pixels in each row of the first pixel driving region 102 and the number of pixels in each row of the second pixel driving region 104 are the same, and a situation where the number of pixels in each row of the first pixel driving region 102 and the number of pixels in each row of the second pixel driving region 104 are close. For example, if the difference in quantity between the two is within ±20%, it can be understood that their quantities are equivalent. For two display regions controlled by the same row addressing region, the number of pixels in each row is equivalent, which is beneficial for balancing the load on both sides of the row addressing region and improving its efficiency.

In some embodiments, the number of pixels in each row of the fifth pixel driving region 110 is equal to the number of pixels in each row of the sixth pixel driving region 111.

The embodiments of the present disclosure further provide a method for manufacturing a display substrate. The manufacturing method can be used to produce the display substrate in the various embodiments described above. The manufacturing method may include the following steps:
providing a base;
forming a row addressing region, a first pixel driving region, and a second pixel driving region on the base, where the row addressing region is provided with a row addressing circuit; the first pixel driving region is on one side of the row addressing region, and is provided with a pixel circuit; and the second pixel driving region is on the other side of the row addressing region, and is provided with a pixel circuit; where the row addressing region is between the first pixel driving region and the second pixel driving region;
where the row addressing circuit includes:
a scan driving circuit;
a first gating circuit between the scan driving circuit and the first pixel driving region, where the first gating circuit connects the scan driving circuit and the pixel circuit in the first pixel driving region; and
a second gating circuit between the scan driving circuit and the second pixel driving region, where the second gating circuit connects the scan driving circuit and the pixel circuit in the second pixel driving region.

In some embodiments, the manufacturing method further includes:
forming a driving circuit layer on a side of the base, where the driving circuit layer includes pixel circuits in the first pixel driving region and the second pixel driving region, and a row addressing circuit in the row addressing region, where each of the pixel circuit in the first pixel driving region, the pixel circuit in the second pixel driving region, and the row addressing circuit in the row addressing region includes a capacitor and thin film transistors; and
forming an organic light-emitting layer on a side of the driving circuit layer away from the base.

The embodiments of the present disclosure further provide a display device including a display substrate as described in any of the above embodiments.

In some embodiments, the display device further includes a housing, and the display substrate is embedded within the housing.

The display device provided in the embodiments of the present disclosure can be any suitable display device, including but not limited to mobile phones, tablets, televisions, displays, laptops, digital photo frames, navigation devices, e-books, and any other products or components with display functions.

It should be pointed out that in the attached figures, the dimensions of the layers and regions may be exaggerated for clarity. And it can be understood that when a component or layer is referred to as “on” another component or layer, it can be directly on the another components, or there can be an intermediate layer. Furthermore, it can be understood that when a component or layer is referred to as “under” another component or layer, it can be directly under the another component, or there may be at least one intermediate layer or component. Additionally, it can be understood that when a layer or component is referred to as “between” two layers or two components, it can be the only layer between the two layers or two components, or there can be at least one intermediate layer or component. Similar reference marks throughout indicate similar components.

After considering and practicing the disclosure of the specification, other embodiments of the present disclosure will be readily apparent to those skilled in the art. The present disclosure is intended to cover any modification, use or adaptation of the present disclosure. These modifications, uses or adaptations follow the general principles of the present disclosure and include common knowledge and conventional technical means in the technical field that are not disclosed in the present disclosure. The specification and embodiments herein are intended to be illustrative only and the real scope and spirit of the present disclosure are indicated by the following claims of the present disclosure.

It is to be understood that the present disclosure is not limited to the precise structures described above and shown in the accompanying drawings and may be modified or changed without departing from the scope of the present disclosure. The scope of the present disclosure is limited only by the attached claims.

1. A display substrate, comprising:
a row addressing circuit in a row addressing region;
a first pixel circuit in a first pixel driving region on one side of the row addressing region; and
a second pixel circuit in a second pixel driving region, on another side of the row addressing region, wherein the row addressing region is between the first pixel driving region and the second pixel driving region;
wherein the row addressing circuit comprises:
a scan driving circuit;
a first gating circuit between the scan driving circuit and the first pixel driving region, wherein the first gating circuit connects the scan driving circuit and the first pixel circuit; and
a second gating circuit between the scan driving circuit and the second pixel driving region, wherein the second gating circuit connects the scan driving circuit and the second pixel circuit.

2. The display substrate according to claim 1, further comprising:
a base;
a driving circuit layer on the base; and
an organic light-emitting layer on the driving circuit layer and away from the base;
wherein the driving circuit layer comprises the row addressing circuit of the row addressing region.

3. The display substrate according to claim 2, wherein the first pixel circuit and the second pixel circuit are in the driving circuit layer, and the first pixel circuit comprises a first capacitor and first thin film transistors and is configured to control light emission of a first pixel, and the second pixel circuit comprises a second capacitor and second thin film transistors and is configured to control light emission of a second pixel;
wherein the row addressing circuit is in a same layer as the first pixel circuit and the second pixel circuit.

4. (canceled)

5. The display substrate according to claim 2, further comprising: a bottom shielding layer between the base and the driving circuit layer;
wherein the bottom shielding layer comprises connecting wires and shielding patterns, wherein the connecting wires electrically connect the shielding patterns;
wherein one of the shielding patterns comprises a horizontal shielding line extending along a first direction, a vertical shielding line extending along a second direction, and a square shielding block at an intersection of the horizontal shielding line and the vertical shielding line.

6-8. (canceled)

9. The display substrate according to claim 2, wherein the driving circuit layer comprises:
a first active layer;
a first gate layer;
a second gate layer on the first gate layer and away from the base;
a second active layer; and
a third gate layer on the second gate layer and away from the base;
wherein the first active layer comprises amorphous silicon or polycrystalline silicon.

10. (canceled)

11. The display substrate according to claim 9, wherein the first active layer comprises first active regions, wherein each of the first active regions corresponds to a thin film transistor or a plurality of electrically connected thin film transistors; and
the first active regions are in the row addressing region, the first pixel driving region, and the second pixel driving region.

12. The display substrate according to claim 9, wherein the first gate layer in the first pixel driving region and the second pixel driving region comprises a first type gate line extending along the first direction, and gate pattern blocks;
wherein the gate pattern block is block-shaped, and some of the gate pattern blocks are arranged in a row along a first direction.

13. The display substrate according to claim 9, wherein the first gate layer in the row addressing region comprises a first type gate line extending along a first direction, a second type gate line extending both along the first direction and a second direction, block-shaped gate pattern blocks, and U-shaped third type gate lines;
wherein the third type gate line comprises a horizontal connecting line extending along the first direction, and two vertical gate portions respectively arranged at both ends of the horizontal connecting line, wherein the two vertical gate portions are parallel and spaced apart from each other.

14. (canceled)

15. The display substrate according to claim 9, wherein the first gate layer comprises a first gate connecting line for connecting a gate line on any one of two sides of the row addressing region;
wherein the first gate connecting line comprises a gate connecting end connecting the gate line, an away gate end in the row addressing region and away from the gate line, and a winding line segment between the gate connecting end and the away gate end and connecting the gate connecting end and the away gate end, wherein the gate connecting end, the away gate end or both extend along a first direction, and the winding line segment extends along a second direction.

16. (canceled)

17. The display substrate according to claim 9, wherein the first gate layer comprises a second gate connecting line for connecting a gate line on any one of two sides of the row addressing region, one end of the second gate connecting line is connected to the gate line, and another end of the second gate connecting line does not extend to a region of the scan driving circuit of the row addressing region.

18. The display substrate according to claim 9, wherein the second gate layer in the first pixel driving region and the second pixel driving region comprises a fourth type gate line extending along a first direction, and gate pattern blocks;
wherein at least one portion of the fourth type gate line and a corresponding portion of the first gate layer form a capacitor, and at least one portion of one of the gate pattern blocks and a corresponding portion of the first gate layer form a capacitor.

19. The display substrate according to claim 9, wherein the second gate layer in the row addressing region comprises a fourth type gate line extending along a first direction, a fifth type gate line extending both along the first direction and a second direction, block-shaped gate pattern blocks, and U-shaped sixth type gate lines;
wherein the sixth type gate line comprises a horizontal connecting line extending along the first direction, and two vertical gate portions respectively arranged at both ends of the horizontal connecting line, wherein the two vertical gate portions are parallel and spaced apart from each other;
wherein one of the gate pattern blocks and a corresponding portion of the first gate layer form a capacitor.

20. (canceled)

21. The display substrate according to claim 9, wherein the second gate layer comprises a third gate connecting line for connecting a gate line on any one of two sides of the row addressing region;
wherein the third gate connecting line comprises a middle connecting segment, two near gate ends, and two vertical segments, wherein the middle connecting segment is in a middle region of the row addressing region and extends along the first direction to both sides of the row addressing region, the two near gate ends are on opposite sides of the gate connecting line along the first direction, and the vertical segments each extend along the second direction and are connected between the middle connecting segment and one of the two near gate ends.

22. (canceled)

23. The display substrate according to claim 9, wherein the third gate layer in the first pixel driving region and the second pixel driving region comprises a first type gate line extending along a first direction.

24. The display substrate according to claim 9, wherein the third gate layer in the row addressing region comprises a first type gate line extending along a first direction, a second type gate line extending both along the first direction and a second direction, and U-shaped third type gate lines;
wherein the third type gate line comprises a horizontal connecting line extending along the first direction, and two vertical gate portions respectively arranged at both ends of the horizontal connecting line, wherein the two vertical gate portions are parallel and spaced apart from each other.

25. The display substrate according to claim 9, wherein the third gate layer comprises a third gate connecting line for connecting a gate line on any one of two sides of the row addressing region;
wherein the third gate connecting line comprises a middle connecting segment, two near gate ends, and two vertical segments, wherein the middle connecting segment is in a middle region of the row addressing region and extends along the first direction to both sides of the row addressing region, the two near gate ends are located on opposite sides of the gate connecting line along the first direction, and the vertical segments each extends along the second direction and is connected between the middle connecting segment and one of the two near gate ends.

26. The display substrate according to claim 1, further comprising:
a second row addressing circuit in a second row addressing region at an edge of the display substrate; and
a third pixel driving region between the second row addressing region and the first pixel driving region;
wherein the second row addressing circuit comprises:
a second scan driving circuit;
a third gating circuit between the second scan driving circuit and the third pixel driving region, wherein the third gating circuit connects the second scan driving circuit and a third pixel circuit in the third pixel driving region; and
a third row addressing circuit in a third row addressing region at another edge of the display substrate;
wherein the third row addressing circuit comprises:
a third scan driving circuit;
a fourth gating circuit between the third scan driving circuit and a fourth pixel driving region between the second pixel driving region and the third row addressing region, wherein the fourth gating circuit connects the third scan driving circuit and a pixel circuit in the fourth pixel driving region; and
a fourth row addressing circuit in a fourth row addressing region ;
wherein the fourth row addressing circuit comprises:
a fourth scan driving circuit;
a fifth gating circuit between the fourth scan driving circuit and a fifth pixel driving region between the fourth row addressing region and the third pixel driving region, wherein the fifth gating circuit connects the fourth scan driving circuit and a pixel circuit in the fifth pixel driving region.
a sixth gating circuit between the fourth scan driving circuit and a sixth pixel driving region between the fourth row addressing region and the first pixel driving region, wherein the sixth gating circuit connects the fourth scan driving circuit and a pixel circuit in the sixth pixel driving region;
wherein a number of pixels in each row of the first pixel driving region is equal to a number of pixels in each row of the second pixel driving region and/or a number of pixels in each row of the fifth pixel driving region is equal to a number of pixels in each row of the sixth pixel driving region.

27-29. (canceled)

30. The display substrate according to claim 1, wherein a refresh rate of the first pixel driving region and a refresh rate of the second pixel driving region are independently controlled by the row addressing circuit of the row addressing region.

31. A method for manufacturing a display substrate, wherein the method comprises:
providing a base;
forming a row addressing region, a first pixel driving region, and a second pixel driving region on the base, wherein the row addressing region is provided with a row addressing circuit; the first pixel driving region is on one side of the row addressing region, and is provided with a pixel circuit; and the second pixel driving region is on the other side of the row addressing region, and is provided with a pixel circuit; wherein the row addressing region is between the first pixel driving region and the second pixel driving region;
wherein the row addressing circuit comprises:
a scan driving circuit;
a first gating circuit between the scan driving circuit and the first pixel driving region, wherein the first gating circuit connects the scan driving circuit and the pixel circuit in the first pixel circuit; and
a second gating circuit between the scan driving circuit and the second pixel driving region, wherein the second gating circuit connects the scan driving circuit and the pixel circuit in the second pixel circuit.

32. (canceled)

33. A display device, comprising a display, wherein the display substrate comprises:
a row addressing circuit in a row addressing region;
a first pixel circuit in a first pixel driving region on one side of the row addressing region; and
a second pixel circuit in a second pixel driving region on another side of the row addressing region, wherein the row addressing region is between the first pixel driving region and the second pixel driving region;
wherein the row addressing circuit comprises:
a scan driving circuit;
a first gating circuit between the scan driving circuit and the first pixel driving region, wherein the first gating circuit connects the scan driving circuit and the first pixel circuit; and
a second gating circuit between the scan driving circuit and the second pixel driving region, wherein the second gating circuit connects the scan driving circuit and the second pixel circuit.
